(19) United States
(12) Patent Application Publication
(10) Pub. No.: US 2004/0201009 A1
(43) Pub. Date: Oct. 14, 2004

(54) Infrared photodetector

(75) Inventors: Buo-Chin Hsu, Yonghe City (TW); Shu-Tong Chang, Taoyuan County (TW); Shi-Hao Huang, Taipei City (TW); Chee-Wee Liu, Taipei City (TW)

Correspondence Address: BEVER HOFFMAN & HARMS, LLP, TRI-VALLEY OFFICE, 1432 CONCANNON BLVD., BLDG. G, LIVERMORE, CA, 94550, US

(73) Assignee: National Taiwan University, Taipei City (TW)

(21) Appl. No.: 10/817,113

(22) Filed: Apr. 1, 2004

(30) Foreign Application Priority Data
Apr. 10, 2003 (TW) 092108185

(51) Int. Cl. H01L 31/0328

(52) U.S. Cl. 257/21; 257/449; 257/458

(57) ABSTRACT

An infrared photodetector formed of a MOS tunneling diode is disclosed. The infrared photodetector comprises a conducting layer, a semiconductor layer comprising at least one layer of quantum structure for confining a carrier in a barrier, an insulating layer formed between the conducting layer and the semiconductor layer, and a voltage source connected to the conducting layer and the semiconductor layer for providing a bias voltage to generate a quantum tunneling effect, such that the carrier penetrates through the insulating layer to form a current, wherein when irradiated by an infrared, the carrier in the barrier absorbs the energy of the infrared to jump out of the barrier and is collected by an electrode to form a photocurrent.

### FIELD OF THE INVENTION

The present invention relates to an infrared photodetector, and more particularly to a photodetector used in an infrared image detecting device.

### BACKGROUND OF THE INVENTION

In U.S. Pat. No. 6,268,615, the MOS tunneling diode has been used as a photodetector, but its detecting wavelength is limited to the material bandgap, since additional electron hole pairs could only be produced when the photon energy is larger than the material bandgap. If a Si substrate is employed, the detecting wavelength limit is about 1.1 μm; if a Ge substrate is employed, the detecting wavelength limit is about 1.85 μm.

The infrared photodetector is widely used in military affairs and astronomy. Most of the current infrared photodetectors are made of Ill-V group semiconductor materials and are metal-semiconductor-metal (MSM) structures. The manufacturing cost thereof is high and the subsequent circuit design is complex, so it is not suitable for mass production.

Therefore, the purpose of the present invention is to increase the application range of the MOS photodetector to be able to detect infrared.

### SUMMARY OF THE INVENTION

It is an object of the present invention to provide an infrared photodetector.

In accordance with an aspect of the present invention, the infrared photodetector comprises a conducting layer, a semiconductor layer comprising at least one layer of quantum structure for confining a carrier in a barrier, an insulating layer formed between the conducting layer and the semiconductor layer, and a voltage source connected to the conducting layer and the semiconductor layer for providing a bias voltage to generate a quantum tunneling effect, such that the carrier penetrates through the insulating layer to form a current, wherein when irradiated by an infrared, the carrier in the barrier absorbs the energy of the infrared to jump out of the barrier and is collected by an electrode to form a photocurrent.

Preferably, the conducting layer is one of an aluminum layer and a doped polysilicon layer.

Preferably, the conducting layer is a transparent conductor.

Preferably, the transparent conductor is made of indium tin oxide (ITO).

Preferably, the conducting layer is one of a reticular conducting layer and a lattice conducting layer.

Preferably, the semiconductor layer is one of a p-type semiconductor and an n-type semiconductor.

Preferably, the quantum structure is one of a quantum dot and a quantum well.

Preferably, the semiconductor layer comprises a Si substrate and plural layers of quantum structures formed on the Si substrate.

Preferably, the quantum structure comprises a Ge wetting layer, a Ge quantum dot and a Si layer.

Preferably, the insulating layer is a silicon oxide layer.

Preferably, the insulating layer has a thickness of 1 to 10 nm.

Preferably, the insulating layer is formed by a liquid phase deposition.

In accordance with another aspect of the present invention, the infrared photodetector comprises a conducting layer, a p-type semiconductor layer comprising at least one layer of quantum structure for confining a carrier in a barrier, an insulating layer formed between the conducting layer and the p-type semiconductor layer, and a voltage source with a positive electrode connected to the conducting layer and with a negative electrode connected to the p-type semiconductor layer for providing a bias voltage to generate a quantum tunneling effect, such that the carrier penetrates through the insulating layer to form a current, wherein when irradiated by an infrared, the carrier in the barrier absorbs the energy of the infrared to jump out of the barrier and is collected by the electrode to form a photocurrent.

In accordance with an additional aspect of the present invention, the infrared photodetector comprises a conducting layer, an n-type semiconductor layer comprising at least one layer of quantum structure for confining a carrier in a barrier, an insulating layer formed between the conducting layer and the n-type semiconductor layer, and a voltage source with a negative electrode connected to the conducting layer and with a positive electrode connected to the n-type semiconductor layer for providing a bias voltage to generate a quantum tunneling effect, such that the carrier penetrates through the insulating layer to form a current, wherein when irradiated by an infrared, the carrier in the barrier absorbs the energy of the infrared to jump out of the barrier and is collected by the electrode to form a photocurrent.

The above objectives and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 shows a schematic view of the infrared photodetector according to a preferred embodiment of the present invention;

FIG. 2 shows the working energy band diagram of the infrared photodetector according to a preferred embodiment of the present invention;

FIG. 3 shows the voltage-current characteristic diagram of the gate of the infrared photodetector according to a preferred embodiment of the present invention;

FIG. 4 shows the frequency response spectrum of the infrared photodetector according to a preferred embodiment of the present invention under different infrared wavelengths; and

FIG. 5 shows a schematic view of the infrared photodetector according to another preferred embodiment of the present invention.

### DETAILED DESCRIPTION OF THE PREFERRED EMBODIMENT

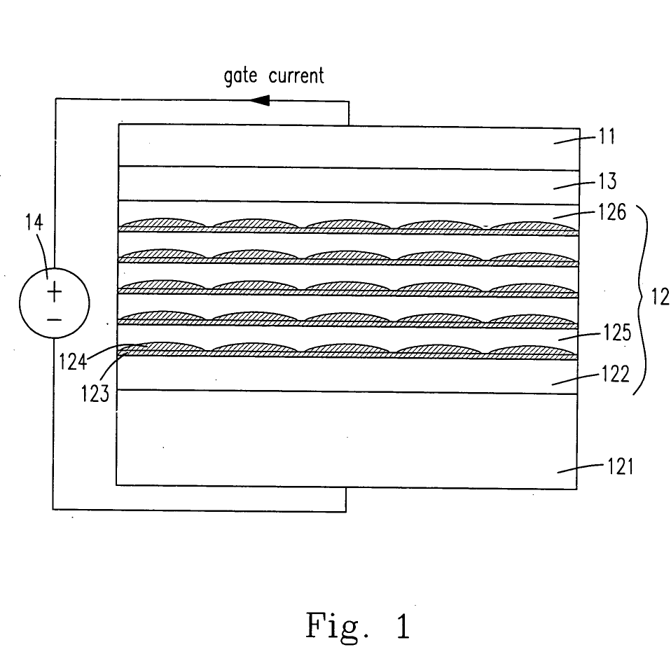

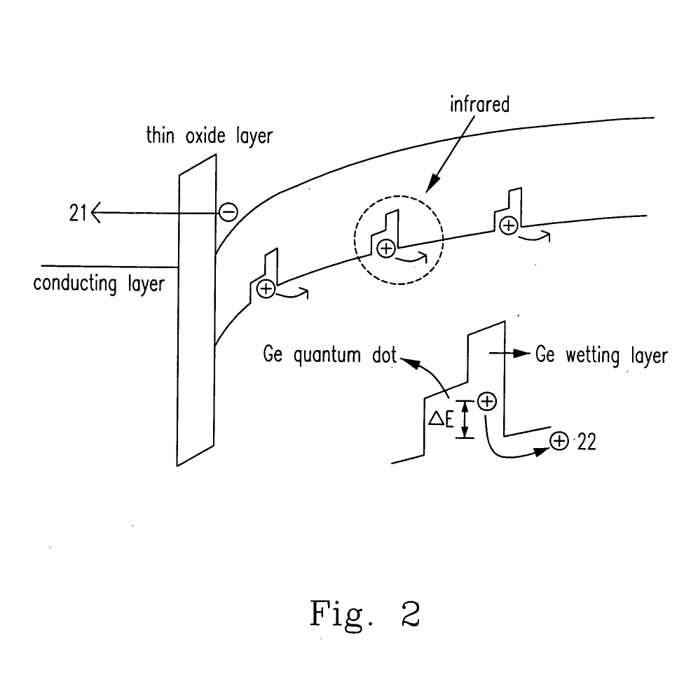

Please refer to FIG. 1 showing a schematic view of the infrared photodetector according to a preferred embodiment of the present invention. The infrared photodetector mainly comprises a conducting layer 11, a p-type semiconductor layer 12 having five layers of Ge quantum dots, an insulating layer 13 and a voltage source 14. The semiconductor layer 12 further comprises a Si substrate 121, a Si buffer layer 122, a Ge wetting layer 123, a Ge quantum dot 124, a Si spacer layer 125 and a Si cap layer 126. When the p-type semiconductor layer 12 is not irradiated, electron hole pairs are naturally produced in the interface trap between the p-type semiconductor layer 12 having five layers of Ge quantum dots and the insulating layer 13, and the trap in the semiconductor material. As shown in the energy band diagram of FIG. 2, since the bandgap of Ge material is smaller than that of Si, some produced holes are confined in the energy barrier due to the quantum effect. At room temperature, the confined holes can jump out of the barrier by absorbing the heat energy. In the meantime, if the working bias voltage provided by the voltage source 14 (with a positive electrode connected to the conducting layer 11 and with a negative electrode connected to the p-type semiconductor layer 12) is a positive voltage, the energy of the insulating layer 13 close to the conducting layer 11 would reduce and the penetrating ability of the electrons would increase to generate the quantum tunneling effect. Therefore, under a sufficient positive bias voltage, the electrons can penetrate through the thin insulating layer 13 to the conducting layer 11. The current detected at this time is called a dark current 21.

Lacking of heat energy at low temperature, the holes confined in the quantum wells cannot jump out of the barrier. Also, since the number of the electron hole pairs produced in the interface trap and the material trap reduces, the dark current reduces accordingly. Based on the quantum mechanics, the holes in the quantum wells would produce a discontinuous energy level distribution, and the holes would occupy different energy levels and are confined in the quantum wells, as shown in FIG. 2. Although the materials of the Ge wetting layer 124 and the Ge quantum dot 125 are both germanium, the stresses thereof are different, so the bandgaps of the two layers are somewhat different, as shown in FIG. 2. If the elements are irradiated by an infrared, although the photon energy is smaller than the material bandgap and additional electron hole pairs cannot be produced via interband transition, the holes confined in the quantum wells can absorb the energy ΔE of the infrared and jump out of the barrier. Then the holes are attracted by the negative voltage and are collected by the negative electrode to form a photocurrent 22.

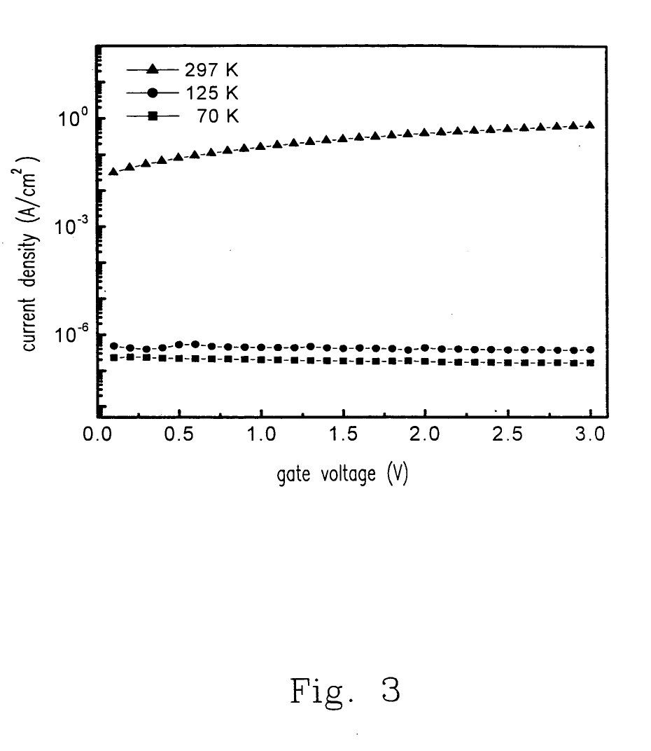

For illustrating the feature of the present invention, please refer to FIG. 3 showing the voltage-current characteristic diagram of the gate of the infrared photodetector according to a preferred embodiment of the present invention. In which, the p-type semiconductor layer 12 uses p-type Si with a doped concentration of about 1016 cm⁻³ as a substrate 121. Then a Si buffer layer 122 of 50 nm, a Ge wetting layer 123 of 2 nm, a Ge quantum dot layer 124 of 6 nm and a Si spacer layer of 50 nm, all of which have a doped concentration of about 1016 cm⁻³, are grown on the Si substrate 121 respectively by ultra high vacuum chemical deposition. After five layers of Ge quantum dots are formed, a Si cap layer 126 of 3 nm is finally grown thereon. The insulating layer 13 is grown on the surface of the p-type semiconductor layer 12 having five layers of Ge quantum dots by liquid phase deposition, in which the insulating layer 13 is a thin silicon oxide layer and has a thickness of 1 to 10 nm, preferably 1.5 nm. The conducting layer 11 is formed by plating an aluminum layer on the surface of the insulating layer 13 and photolithographically etching the aluminum layer to form an aluminum electrode having an area of about 3×10⁻⁴ cm². FIG. 3 shows the gate current read in the gate formed by the aluminum electrode under different bias voltage (or gate voltage) provide by the voltage source 14 at room temperature or low temperature. It is found that the dark current is greatly affected by the temperature, in which the lower the temperature, the smaller the dark current.

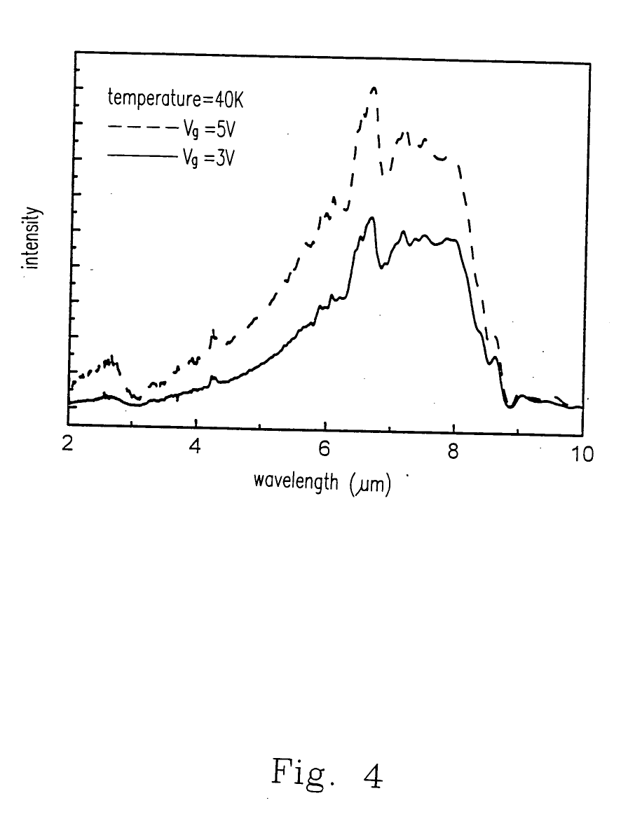

Please refer to FIG. 4 showing the frequency response spectrum of the infrared photodetector according to a preferred embodiment of the present invention under different infrared wavelengths at the temperature of 40K. When the irradiating infrared wavelength is longer than 1.85 μm, i.e. the energy thereof is smaller than 0.67 eV (equals to Ge bandgap), the holes confined in the quantum wells can absorb the infrared and jump out of the barrier, and then are collected by the electrode to produce an optical signal. When the gate bias voltage is larger (5 V), the optical signal is larger (compared to the response under the gate bias voltage of 3 V). In the meantime, since the quantum wells are more inclined under higher bias voltage, more holes confined in the quantum wells can absorb the infrared and jump out of the barrier to produce the optical signal. Therefore, the infrared photodetector of the present invention can effectively detect the light whose wavelength is longer than the bandgap wavelength of Ge and Si. In addition, the infrared photodetector of the present invention can also detect the light whose wavelength is shorter than the bandgap wavelength of Ge and Si.

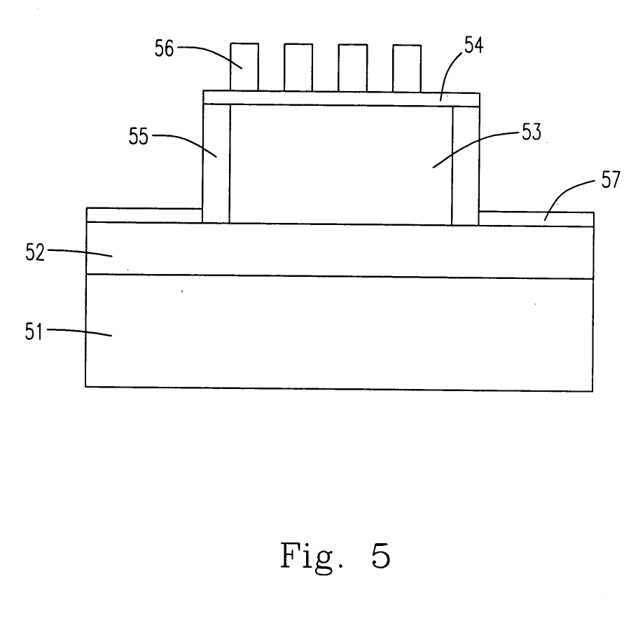

Please refer to FIG. 5 showing a schematic view of the infrared photodetector according to another preferred embodiment of the present invention. The infrared photodetector mainly comprises a silicon or silicon on insulator (SOI) substrate 51, a highly doped silicon layer 52, a semiconductor layer 53 having at least one layer of quantum well or quantum dot, an insulating layer 54, an insulating isolation layer 55, a reticular electrode 56 and an electrode 57. The highly doped silicon layer 52 is used to rapidly conduct the carriers to the electrode 57. The insulating isolation layer 55 is used to isolate the electrode 57 and the semiconductor layer 53 having at least one layer of quantum well or quantum dot. The reticular electrode 56 can increase the irradiating area of the elements and the conducting rate of the carriers. Therefore, the infrared photodetector according to this preferred embodiment of the present invention can also effectively detect the light of various wavelengths (including the light whose wavelength is shorter or longer than the material bandgap).

The conducting layer of the infrared photodetector in the present invention can be made of aluminum or doped polysilicon. For increasing the irradiating effect, the conducting layer can also be a transparent conductor made of indium tin oxide (ITO). In addition, the conducting layer can be a reticular structure or a lattice structure. Furthermore, the semiconductor layer can also be an n-type, rather than p-type, semiconductor layer, and the materials thereof are not limited to Si and Ge.

In conclusion, the infrared photodetector of the present invention employs the characteristic that different materials have different bandgaps, and forms the quantum structures of quantum dots and quantum wells, such that the carriers are confined in the barrier at proper temperature and can jump out of the barrier by absorbing the infrared so as to produce the optical signal. Moreover, the infrared photodetector of the present invention can detect not only the light whose wavelength is longer than the material bandgap, but also the light whose wavelength is shorter than the material bandgap. The distinction therebetween is that the physical mechanisms for producing the optical signal are different. For the optical signal whose energy is larger than the material bandgap, the electron hole pairs are produced by interband transition to form the photocurrent; while for the optical signal whose energy is smaller than the material bandgap, the carriers are confined in the barrier formed from the structures of quantum wells and quantum dots, and the optical signal is produced by intraband transition.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An infrared photodetector, comprising:
a conducting layer;
a semiconductor layer comprising at least one layer of quantum structure for confining a carrier in a barrier;
an insulating layer formed between said conducting layer and said semiconductor layer; and
a voltage source connected to said conducting layer and said semiconductor layer for providing a bias voltage to generate a quantum tunneling effect, such that said carrier penetrates through said insulating layer to form a current;
wherein when irradiated by an infrared, said carrier in said barrier absorbs the energy of said infrared to jump out of said barrier and is collected by an electrode to form a photocurrent.

2. The infrared photodetector according to claim 1 wherein said conducting layer is one of an aluminum layer and a doped polysilicon layer.

3. The infrared photodetector according to claim 1 wherein said conducting layer is a transparent conductor.

4. The infrared photodetector according to claim 3 wherein said transparent conductor is made of indium tin oxide (ITO).

5. The infrared photodetector according to claim 1 wherein said conducting layer is one of a reticular conducting layer and a lattice conducting layer.

6. The infrared photodetector according to claim 1 wherein said semiconductor layer is one of a p-type semiconductor and an n-type semiconductor.

7. The infrared photodetector according to claim 1 wherein said quantum structure is one of a quantum dot and a quantum well.

8. The infrared photodetector according to claim 1 wherein said semiconductor layer comprises a Si substrate and plural layers of quantum structures formed on said Si substrate.

9. The infrared photodetector according to claim 1 wherein said quantum structure comprises a Ge wetting layer, a Ge quantum dot and a Si layer.

10. The infrared photodetector according to claim 1 wherein said insulating layer is a silicon oxide layer.

11. The infrared photodetector according to claim 1 wherein said insulating layer has a thickness of 1 to 10 nm.

12. The infrared photodetector according to claim 1 wherein said insulating layer is formed by a liquid phase deposition.

13. An infrared photodetector, comprising:
a conducting layer;
a p-type semiconductor layer comprising at least one layer of quantum structure for confining a carrier in a barrier;
an insulating layer formed between said conducting layer and said p-type semiconductor layer; and
a voltage source with a positive electrode connected to said conducting layer and with a negative electrode connected to said p-type semiconductor layer for providing a bias voltage to generate a quantum tunneling effect, such that said carrier penetrates through said insulating layer to form a current;
wherein when irradiated by an infrared, said carrier in said barrier absorbs the energy of said infrared to jump out of said barrier and is collected by said electrode to form a photocurrent.

14. An infrared photodetector, comprising:
a conducting layer;
an n-type semiconductor layer comprising at least one layer of quantum structure for confining a carrier in a barrier;
an insulating layer formed between said conducting layer and said n-type semiconductor layer; and
a voltage source with a negative electrode connected to said conducting layer and with a positive electrode connected to said n-type semiconductor layer for providing a bias voltage to generate a quantum tunneling effect, such that said carrier penetrates through said insulating layer to form a current;
wherein when irradiated by an infrared, said carrier in said barrier absorbs the energy of said infrared to jump out of said barrier and is collected by said electrode to form a photocurrent.
